(19) United States
(12) Patent Application Publication
(10) Pub. No.: US 2016/0137146 A1
(43) Pub. Date: May 19, 2016

(54) SHIELDED WIRE AND WIRE HARNESS

(71) Applicant: Yazaki Corporation, Tokyo (JP)

(72) Inventors: Yusuke YANAGIHARA, Kakegawa-shi (JP); Shigeo MORI, Kakegawa-shi (JP); Junya HIGASHI, Kakegawa-shi (JP); Takashi ISHIHARA, Kakegawa-shi (JP)

(73) Assignee: Yazaki Corporation, Tokyo (JP)

(21) Appl. No.: 15/002,650

(22) Filed: Jan. 21, 2016

Related U.S. Application Data
(63) Continuation of application No. PCT/JP2014/072333, filed on Aug. 26, 2014.

(30) Foreign Application Priority Data
Aug. 26, 2013 (JP) 2013-174182

(51) Int. Cl. B60R 16/02; H05K 9/00; H02G 3/04; H01B 7/28

(52) U.S. Cl. CPC B60R 16/0207; H01B 7/28; H05K 9/0098; H02G 3/0406

(57) ABSTRACT

A wire harness includes a surface treated shielded wire and a counterpart connection portion provided at an end of the surface treated shielded wire. The surface treated shielded wire includes a conductor, an insulative coating provided on an outer side of the conductor and having a surface formed with a groove, and an electrically-conductive surface treatment portion applied on at least a surface of the insulative coating other than the groove from one end to the other end, in an extending direction of the conductor, of a predetermined range on the insulative coating.

### CROSS REFERENCE TO RELATED APPLICATIONS

This application is a continuation of International Patent Application No. PCT/JP2014/072333 filed on Aug. 26, 2014, claiming priority from Japanese Patent Application No. 2013-174182 filed on Aug. 26, 2013, the contents of which are incorporated herein by reference.

### FIELD OF INVENTION

The present invention relates to a wire harness, and in particular, to a shielded wire for use in the wire harness.

### BACKGROUND ART

Known shielded wires include those using a braided wire as a shielding member and those using a shielding layer formed by resin plating (see, e.g., JP2012-138280A). The shielded wire using a shielding layer formed by resin plating is disclosed in Patent Document 1 identified below. A wire harness using such shielded wires will be described briefly below.

In FIG. 7, the reference sign 101 represents a high voltage wire harness to be mounted on a vehicle. The wire harness 101 has a configuration including three surface treated shielded wires 102, and shielded connectors 103 provided at respective ends of the surface-treated shielded wires 102.

Each surface-treated shielded wire 102 has a configuration including a conductor 104, an insulative coating 105 and an electrically-conductive surface treatment portion 106. A metal plate having electrical conductivity and formed into a belt-like shape is used as the conductor 104. That is, a metal plate like a bus bar is used. Since the conductor 104 is formed into a shape like a bus bar as described above, it is a matter of course that the conductor 104 has rigidity. In addition, when the conductor 104 is bent, the conductor 104 can keep the bent shape.

The insulative coating 105 is an insulator provided on an outer side of the conductor 104. The insulative coating 105 is formed by extrusion molding out of a resin material having an insulating property. The surface (external surface) of the insulative coating 105 configured thus is formed into a flat surface.

The electrically-conductive surface treatment portion 106 is formed as a shielding layer on the surface of the insulative coating 105 by resin plating for applying plating to a surface of a molded article formed out of a synthetic resin material. The electrically-conductive surface treatment portion 106 is formed in tight contact with the surface of the insulative coating 105. In addition, the electrically-conductive surface treatment portion 106 is formed with a predetermined thickness. The electrically-conductive surface treatment portion 106 is formed as a portion for shielding the insulative coating 105 over a predetermined range. The entire electrically-conductive surface treatment portion 106 has electrical conductivity.

Each shielded connector 103 is used as a portion to be electrically connected to a device 107. The shielded connector 103 has a configuration including a terminal 108, a seal member 109 and a shield shell 110. The insulative coating 105 at a end of the surface treated shielded wire 102 is removed by a predetermined length to from the terminal 108. The terminal 108 is formed into a tab-like shape. The terminal 108 formed thus is connected a counterpart terminal 111 of the device 107.

The device 107 includes a shield case 112 having electrical conductivity, in addition the aforementioned counterpart terminal 111. A through hole 113 is formed in the shield case 112 so that the end of the surface treated shielded wire 102 can be plugged into the through hole 113.

The seal member 109 is a rubber member having electrical conductivity. The seal member 109 is formed so that the end of the surface treated shielded wire 102 can penetrate the seal member 109. In addition, the seal member 109 is formed in tight contact with the surface treated shielded wire 102 so that electric conduction can be secured between the seal member 109 and the electrically-conductive surface treatment portion 106. Further, the seal member 109 is formed in tight contact with the shield case 112 so that moisture etc. can be prevented from invading the shield case 112 through the through hole 113. Furthermore, the seal member 109 is formed so that the seal member 109 can hold the shield shell 110 and electric conduction can be secured between the seal member 109 and the shield shell 110.

The shield shell 110 is a member formed by processing out of a metal plate having electrical conductivity. The shield shell 110 is formed into an annular shape so that the shield shell 110 attached to the seal member 109 can contact with the external surface of the shield case 112. The shield shell 110 is screwed down to the shield shell 112 so as to be fixed thereto.

In the aforementioned configuration and structure, the wire harness 101 is fabricated into a shape intended to be placed in a predetermined wiring path on a vehicle in order to electrically connect the device 107 and a not-shown device, for example, in order to electrically connect an inverter unit and a motor unit. The reference sign 114 represents a bent portion formed at a predetermined place where the surface treated shielded wire 102 is bent in the wire harness 101.

However, the conventional art described above has the following problems.

That is, the thermal expansion coefficient of the insulative coating 105 made of synthetic resin is higher than that of the electrically-conductive surface treatment portion 106 (resin plating). Accordingly, when the deformation of the electrically-conductive surface treatment portion 106 cannot follow the deformation of the insulative coating 105, the electrically-conductive surface treatment portion 106 is wrinkled. When the insulative coating 105 is thermally expanded and contracted repeatedly, the electrically-conductive surface treatment portion 106 is cracked in the wrinkled portion. Such a partial crack in the electrically-conductive surface treatment portion 106 causes deterioration in shield performance. Further, when the electrically-conductive surface treatment portion 106 is broken entirely circumferentially around the insulative coating 105, the shield performance may deteriorate extremely.

The shield performance may also deteriorate due to the following factor. That is, a metal layer formed by resin plating is hardly deformed due to an external force acting thereon, as compared with the insulative coating 105 serving as an underlayer. Therefore, when sudden bending or excessive bending is applied on the surface treated shielded wire 102 or when the surface treated shielded wire 102 is exposed to mechanical stress such as vibration, a large crack or breakage occurs in the electrically-conductive surface treatment portion 106. Such a crack in the electrically-conductive surface treatment portion 106 also causes deterioration in shield performance.

### SUMMARY OF INVENTION

Illustrative aspects of the present invention provides a shielded wire and a wire harness capable of preventing a large crack and breakage and capable of maintaining shield performance even when a crack occurs.

According to an illustrative aspect of the present invention, a shielded wire includes a conductor, an insulative coating provided on an outer side of the conductor and having a surface formed with a recess portion, and an electrically-conductive surface treatment portion applied on at least a surface of the insulative coating other than the recess portion, from one end to another end, in an extending direction of the conductor, of a predetermined range on the insulative coating.

According to these features, the recess portion is formed so that stress is concentrated at the recess portion, and as a result, stress concentration on the surface of the insulative coating other than the recess portion can be relieved. Accordingly, even when the electrically-conductive surface treatment portion has been applied to the recess portion, a crack in the electrically-conductive surface treatment portion can be kept near the recess portion, so that a large crack or breakage of the electrically-conductive surface treatment portion can be prevented. In addition, according to the present invention, the recess portion serves as a stress concentration portion. Therefore, even if the electrically-conductive surface treatment portion is cracked, the electrically-conductive surface treatment portion applied on the recess portion is cracked first so that the electrically-conductive surface treatment portion applied on the surface of the insulative coating can be prevented from being cracked. That is, the electrically-conductive surface treatment portion applied on the surface of the insulative coating can maintain the shield performance. In addition, even if the electrically-conductive surface treatment portion applied on the recess portion is cracked, a conduction path can be secured due to the electrically-conductive surface treatment portion applied on the surface other than the recess portion from one end to the other end.

The recess portion may be formed at a location on the insulative coating corresponding to a bent portion of the shielded wire.

According to these features, even when stress is applied, for example, at the time of wire bending, the stress is concentrated at the recess portion so that stress concentration on the surface of the insulative coating other than the recess portion can be relieved. Accordingly, even when the electrically-conductive surface treatment portion is applied to the recess portion, a crack in the electrically-conductive surface treatment portion can be kept near the recess portion, so that a large crack or breakage of the electrically-conductive surface treatment portion can be prevented.

The shielded wire described above may further include a first electrically-conductive member provided in the recess portion.

According to these features, conduction can be secured in the electrically-conductive surface treatment portion due to the first electrically-conductive member even when the electrically-conductive surface treatment portion applied on the recess portion is cracked.

The shielded wire described above may further include a second electrically-conductive member provided in contact with the surface of the insulative coating.

According to these features, conduction can be secured more surely in the electrically-conductive surface treatment portion due to the second electrically-conductive member even when the electrically-conductive surface treatment portion applied on the surface of the insulative coating is cracked.

According to another illustrative aspect of the present invention, a wire harness includes the shielded wire described above, and a counterpart connection portion provided at an end of the shielded wire, the counterpart connection portion being electrically connected to the electrically-conductive surface treatment portion.

According to these features, it is possible to make electric connection, for example, between devices, and it is also possible to maintain shield performance between devices.

According to the illustrative aspects of the present invention, there is an advantage that it is possible to prevent an electrically-conductive surface treatment portion from being cracked or broken due to thermal expansion or thermal contraction of the insulative coating or prevent the electrically-conductive surface treatment portion from being cracked or broken due to bending of the shielded wire or mechanical stress such as vibration. According to the present invention, there is an advantage that it is therefore possible to maintain shield performance.

### BRIEF DESCRIPTION OF THE DRAWINGS

FIG. 1A includes a diagram of a straight portion of a wire harness and an external view of a surface treated shielded wire according to the present invention (Embodiment 1);

FIG. 1B includes a diagram of a bent portion of the wire harness and an external view of the surface treated shielded wire according to the present invention (Embodiment 1);

FIG. 2 is a sectional view of a terminal portion of the wire harness;

FIG. 3 includes a diagram of a wire harness and an external view of a surface treated shielded wire according to the present invention (Embodiment 2);

FIG. 4 includes a diagram of a wire harness and an external view of a surface treated shielded wire according to the present invention (Embodiment 3);

FIG. 5 includes a diagram of a wire harness and an external view of a surface treated shielded wire according to the present invention (Embodiment 4);

FIG. 6 is a diagram illustrating a location where a wire harness according to the present invention is arranged in a vehicle (Embodiment 5); and

FIG. 7 is a sectional view of a conventional wire harness.

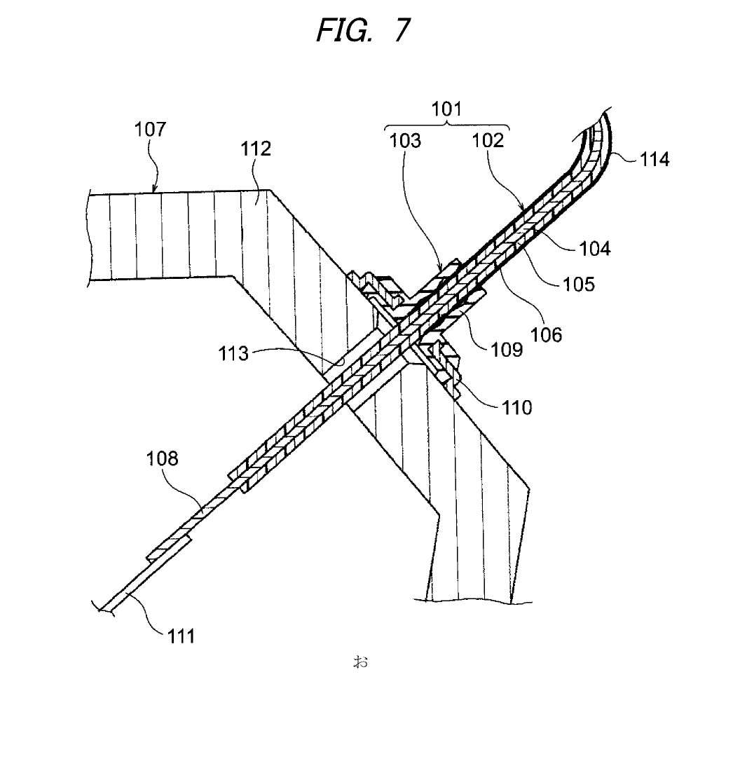

### EMBODIMENTS OF INVENTION

A wire harness has a configuration having a surface treated shielded wire and counterpart connection portion provided at an end of the surface treated shielded wire. The surface treated shielded wire includes a conductor, an insulative coating provided on an outer side of the conductor and having a surface formed with a recess portion, and an electrically-conductive surface treatment portion applied on at least a surface of the insulative coating other than the recess portion from one end to the other end, in the extending direction of the conductor, of a predetermined range on the insulative coating.

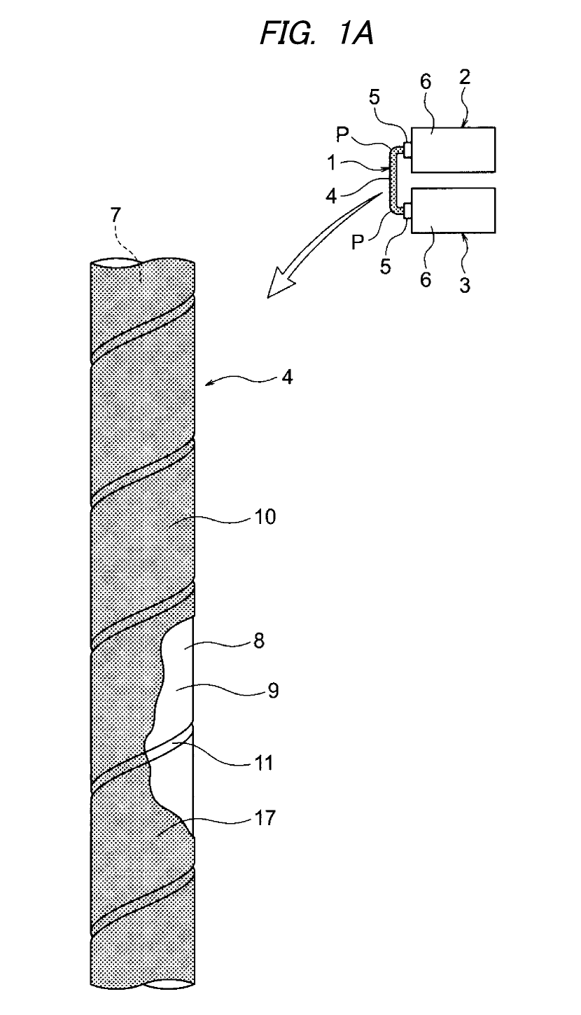

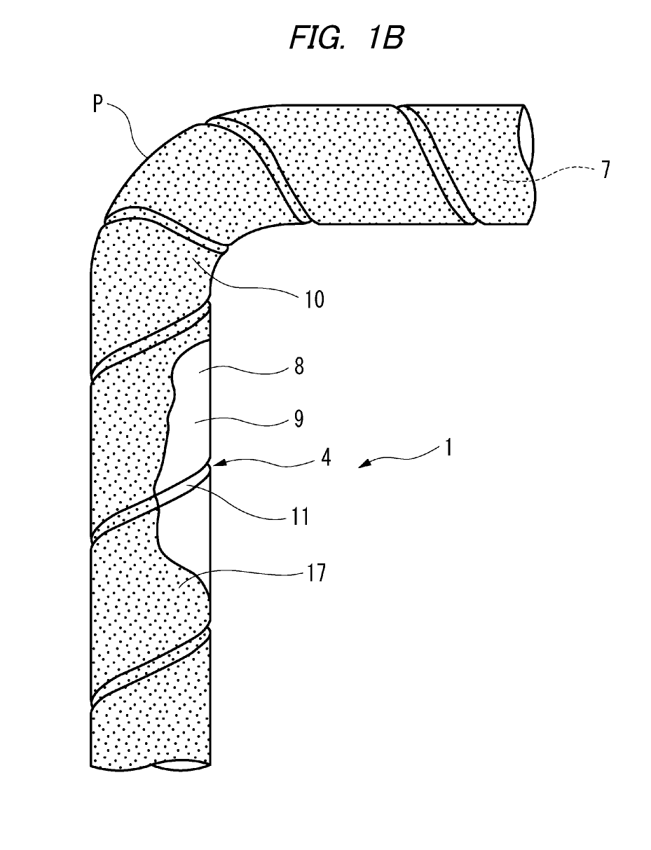

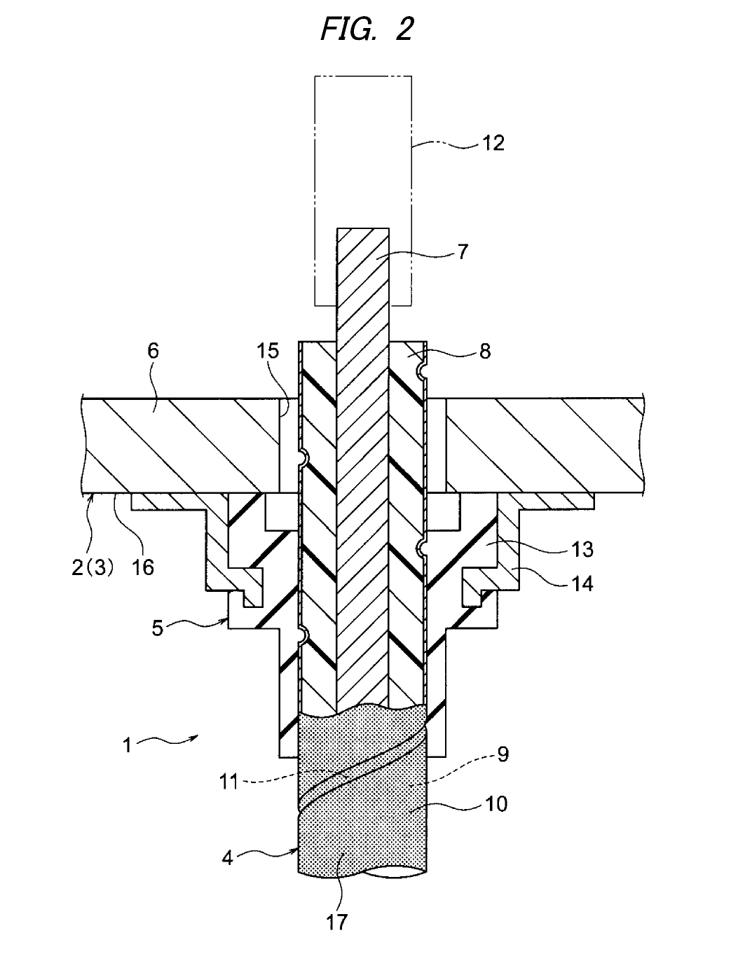

Embodiment 1 will be described below with reference to the drawings. FIG. 1A includes a diagram of a straight portion of a wire harness according to the present invention, and an external view of a surface treated shielded wire. FIG. 1B includes a diagram of a bent portion of the wire harness according to the present invention, and an external view of the surface treated shielded wire. In addition, FIG. 2 is a sectional view of a terminal portion of the wire harness.

In FIG. 1A and FIG. 1B, the reference sign 1 represents a wire harness. The wire harness 1 is a high voltage wire harness for use in an electric car or a hybrid car. The wire harness 1 serves for electrically connecting a high voltage device 2 and a high voltage device 3. However, the wire harness is not limited to such a high voltage one but may be a low voltage one. The wire harness 1 has a configuration including one or more surface treated shielded wires 4, and counterpart connection portions 5, 5 provided at ends of each surface treated shielded wire 4. The wire harness 1 has shield performance by virtue of the surface treated shielded wires 4. The wire harness 1 is electrically connected to shield cases 6, 6 of the respective high voltage device 2, 3. The wire harness 1 is formed so that the wire harness 1 can be wired in a predetermined path between the high voltage device 2, 3.

In FIG. 1A to FIG. 2, the surface treated shielded wire 4 has a configuration including a conductor 7, an insulative coating 8 (insulator) provided on an outer side of the conductor 7, and an electrically-conductive surface treatment portion 10 that is applied to a surface 9 of the insulative coating 8 so as to shield a predetermined range (e.g., a range covering the entire length) in the extending direction of the conductor 7. The surface treated shielded wire 4 is formed into a sectionally circular shape in the embodiment. The sectional shape is exemplary. The sectional shape of the surface treated shielded wire 4 may be a rectangular shape as that in conventional examples.

In each end of the surface treated shielded wire 4, the insulative coating 8 is removed by a predetermined length and processed to expose the conductor 7 having electrical conductivity. That is, the terminal is processed so that it can be connected to a terminal 12, which will be described later. The conductor 7 is made of aluminum, an aluminum alloy, copper or a copper alloy. Here, a conductor structure serving as a twisted wire is used. The conductor structure is exemplary. Specifically, the conductor 7 may have a rod-like conductor structure that is rectangular or circular in section. That is, the conductor 7 may have a conductor structure that serves as a rectangular single core or a circular single core. Alternatively, the conductor 7 may be a bus bar or the like.

The insulative coating 8 is formed out of a resin material having an insulating property and extruded to the outside of the conductor 7. Examples of the resin material may include polyethylene based resin, polypropylene based resin, polyvinylchloride resin, etc. The resin material is not limited especially only if it can apply the electrically-conductive surface treatment portion 10 to the surface 9 of the insulative coating 8. In FIG. 1A and FIG. 1B, while the surface 9 is actually covered with the electrically-conductive surface treatment portion 10, the surface 9 is illustrated in a partially removed manner for the convenience of explanation. The same applies to other embodiments that will be described later.

Since the insulative coating 8 is formed into a cylindrical shape, the sectional shape of the surface treated shielded wire 4 becomes circular. In the surface 9 formed thus, a spiral groove 11 is formed to encircle the axis of the insulative coating 8 spirally. Although the spiral groove 11 is explained in the embodiment, grooves having other shapes than the spiral shape will be described in other embodiments.

The groove 11 is formed by denting the surface 9 toward the conductor 7. For example, the groove 11 is formed by surface processing in which a mold is pressed against the insulative coating 8 that is soft immediately after extrusion molding. The processing method is not limited especially as long as the groove 11 can be formed. In the embodiment, the groove 11 is formed along the entire length of the surface treated shielded wire 4.

The surface 9 is not segmented by the groove 11. That is, no closed loop is formed on the surface 9 by the groove 11, but the surface 9 of the insulative coating 8 is continuous all over the axial length thereof even when the groove 11 is formed. Although the groove 11 is thus formed along the entire length of the surface treated shielded wire 4 in the embodiment, it will go well if the groove 11 is formed and disposed in at least a position corresponding to a place where the surface treated shielded wire 4 is bent (see FIG. 1B. The place will be referred to as wire bent portion P). The pitch and width of the groove 11 are set suitably in accordance with the use form of the wire harness 1. In addition, the depth of the groove 11 is set suitably in consideration of the insulating performance etc.

The groove 11 is formed as a portion on which possible excessive stress applied when, for example, the surface treated shielded wire 4 is bent, can be concentrated in the wire bent portion P. When stress is concentrated on the groove 11, stress acting on the surface 9 of the insulative coating 8 can be relieved. As a result, the electrically-conductive surface treatment portion 10 is suppressed from being cracked or broken. The groove 11 is formed into a U-shape, a V-shape or the like in section. In the embodiment, the groove is explained as a shape of a recess portion according to the present invention by way of example. However, the recess portion is not limited to the groove. A dent having any shape in the surface 9 of the insulative coating 8 may be used as the recess portion in the invention.

The electrically-conductive surface treatment portion 10 is an electrically-conductive surface treatment part applied on the surface 9 and the groove 11 of the insulative coating 8, and in this embodiment, is configured as a shielding layer by resin plating in a similar manner as in conventional examples. Examples of the conductive surface treatment may include conductive painting, vapor deposition, etc. in addition to the aforementioned treatment.

The electrically-conductive surface treatment portion 10 is formed along the entire length of the surface treated shielded wire 4. The electrically-conductive surface treatment portion 10 may be applied to the whole surface of a range that has to be shielded. The electrically-conductive surface treatment portion 10 is formed to be as thick as that in conventional examples. The electrically-conductive surface treatment portion 10 may be formed out of a plurality of layers including an underlayer plating.

The electrically-conductive surface treatment portion 10 is a shielding member reduced in weight, as compared with a braided wire for use in a shielded wire.

Each counterpart connection portion 5 is a shielded connector similar to that in conventional examples. The counterpart connection portion 5 serves as a portion to be electrically connected to the high voltage device 2, 3. The counterpart connection portion 5 has a configuration including a terminal 12, a seal member 13 and a shield shell 14 as shown in FIG. 2.

The terminal 12 is connected to the conductor 7 exposed at a end of the surface treated shielded wire 4. A suitable method such as crimping, pressure contact, fusion, welding, etc. may be used as a method for the connection. The terminal 12 plugged into a through hole 15 of the shield case 6 is electrically connected and fixed to a not-shown counterpart terminal.

The seal member 13 is a member having electrical conductivity and made of rubber. The seal member 13 is formed so that a end of the surface treated shielded wire 4 can penetrate the seal member 13. In addition, the seal member 13 is formed so that the seal member 13 can tightly contact with the surface treated shielded wire 4 so as to secure electric conduction with the electrically-conductive surface treatment portion 10.

Further, the seal member 13 is formed so that the seal member 13 can tightly contact with the shield case 6 so as to prevent moisture etc. from invading the shield case 6 through the through hole 15. Furthermore, the seal member 13 is formed so that the seal member 13 can hold the shield case 14 to secure electric conduction with the shield shell 14.

The shield shell 14 is a member formed out of a metal plate having electrical conductivity by press working. The shield shell 14 is formed into an annular shape that can touch an external surface 16 of the shield case 6 when the shield shell 14 has been attached to the seal member 13. The shield shell 14 is screwed down and fixed to the shield case 6 (with a not-shown screwing portion). On the other hand, the shield shell 14 is intended to secure conduction with the electrically-conductive surface treatment portion 10 of the surface treated shielded wire 4.

In the aforementioned configuration and structure, assume that stress during bending may be, for example, applied on the surface treated shielded wire 4 when the wire harness 1 is wired in a predetermined path. Even in this case, the stress is concentrated on the groove 11 formed in the surface treated shielded wire 4 so that stress concentration on the surface 9 side can be relieved. Thus, a large crack or breakage of the electrically-conductive surface treatment portion 10 is prevented.

As is understood from the above description, the groove 11 serves as a stress concentration portion in the wire harness 1. Accordingly, even if the electrically-conductive surface treatment portion 10 suffers sudden bending or excessive bending or even if the electrically-conductive surface treatment portion 10 is exposed to mechanical stress, the electrically-conductive surface treatment portion 10 applied to the groove 11 can be cracked first, so that the electrically-conductive surface treatment portion 10 applied on the surface 9 of the insulative coating 8 can be prevented from being cracked. That is, the electrically-conductive surface treatment portion 10 applied on the surface 9 of the insulative coating 8 can maintain shield performance.

In addition, the portion of the electrically-conductive surface treatment portion 10 applied on the surface 9 of the insulative coating 8 is formed to be continuous over a range that has to be shielded in the surface treated shielded wire 4. Accordingly, even when the electrically-conductive surface treatment portion 10 applied to the groove 11 is cracked, a conduction path 17 connecting one axial end to the other end within the range can be secured. As a result, the shield performance of the surface treated shielded wire 4 can be maintained surely.

As has been described above with reference to FIG. 1A to FIG. 2, the surface treated shielded wire 4 has an advantage that it is possible to prevent the electrically-conductive surface treatment portion 10 from being cracked or broken due to thermal expansion or thermal contraction of the insulative coating 105 or prevent the electrically-conductive surface treatment portion 10 from being cracked or broken due to bending of the surface treated shielded wire 4 or mechanical stress such as vibration, so that it is therefore possible to maintain shield performance. Further, the wire harness 1 having a configuration including the surface treated shielded wire 4 has an advantage that it is possible to secure electric connection between the high voltage device 2, 3 while maintaining the shield performance. As a result, the wire harness 1 also has an advantage that high reliability can be obtained.

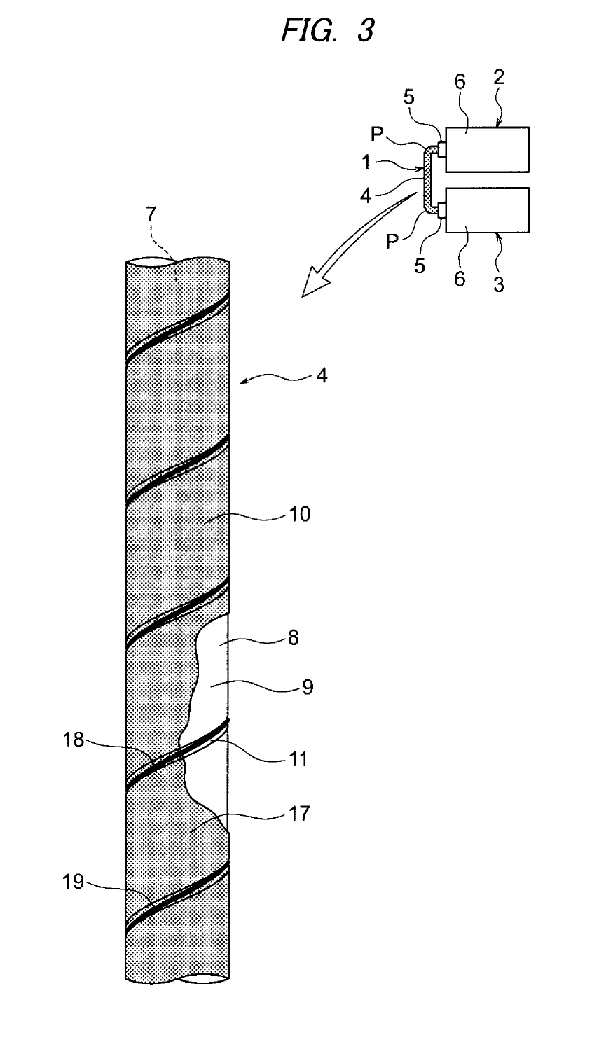

Embodiment 2 will be described below with reference to the drawings. FIG. 3 includes a diagram of a wire harness according to the present invention, and an external view of a surface treated shielded wire. Components that are basically the same as those of Embodiment 1 denoted by the same reference signs, and detailed description thereof will be omitted. In FIG. 3, while the surface 9 is actually covered with the electrically-conductive surface treatment portion 10, the surface 9 is illustrated in a partially removed manner for the convenience of explanation.

In FIG. 3, in a wire harness 1 according to Embodiment 2, a metal wire 18 (first electrically-conductive member) is further provided to the wire harness 1 according to Embodiment 1. That is, the wire harness 1 has a configuration including one or more surface treated shielded wires 4, counterpart connection portions 5, 5 provided at ends of each surface treated shielded wire 4, and metal wires 18.

Each metal wire 18 is a wire having electrical conductivity. The metal wire 18 is provided along a groove 11 of each surface treated shielded wire 4. When an electrically-conductive surface treatment portion 10 is applied to the groove 11, the metal wire 10 touches the electrically-conductive surface treatment portion 10 so as to secure conduction therewith. In addition, the metal wire 18 is provided along the entire length of the surface treated shielded wire 4. As a result, the metal wire 18 is provided to be wound around the surface treated shielded wire 4.

The metal wire 18 is provided as a member capable of securing a conduction path 19 even when the electrically-conductive surface treatment portion 10 applied to the groove 11 is cracked. The metal wire 18 may be replaced by another conductive member as long as it can secure the conduction path 19.

Although the metal wire 18 is provided along the groove 11 in the embodiment, the metal wire 18 is not limited thereto, but may be provided to touch the electrically-conductive surface treatment portion 10 applied to a surface 9 of an insulative coating 8. Specifically, the metal wire 18 may be, for example, provided straightly in the direction of the wire axis.

As has been described above with reference to FIG. 3, the wire harness 1 according to Embodiment 2 has a structure in which the conduction path 19 is further secured by the metal wire 18 in addition to the configuration of Embodiment 1. Due to this structure, there is an advantage that the shield performance can be maintained more surely. As a result, there is also an advantage that the reliability can be improved.

While the embodiment has been described in connection with a case in which the metal wire 18 is received in the groove 11 after the electrically-conductive surface treatment portion 10 is applied to the groove 11, the electrically-conductive surface treatment portion 10 may be applied on the surface 9 of the insulative coating 8 and the groove 11 after the metal wire 18 is received in the groove 11. In the latter case, the electrically-conductive surface treatment portion 10 is applied on the surface of the metal wire 18. Even in this structure, the conduction path 19 can be secured by the metal wire 18.

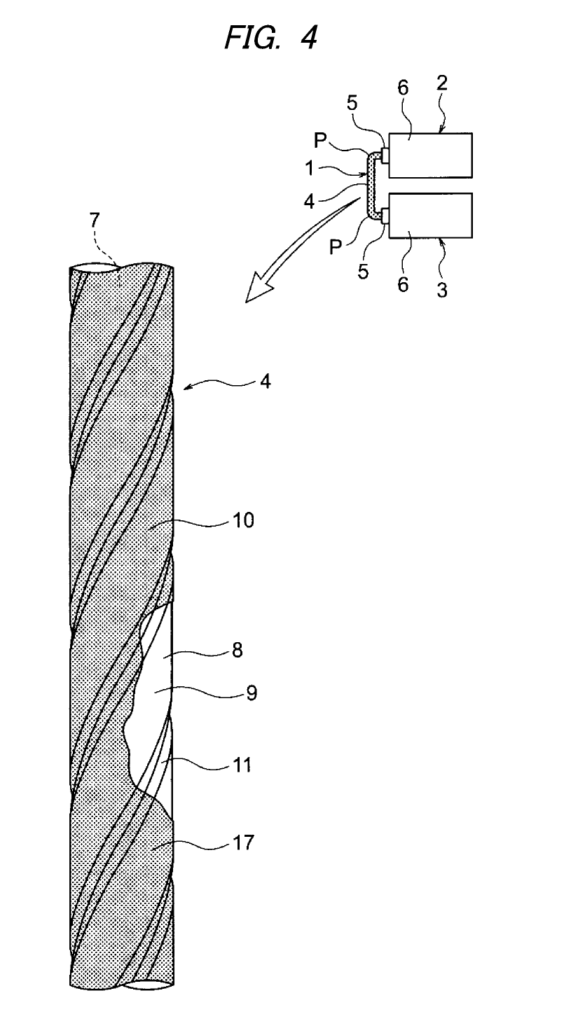

Embodiment 3 will be described below with reference to the drawings. FIG. 4 includes a diagram of a wire harness according to the present invention, and an external view of a surface treated shielded wire. Components that are basically the same as those of Embodiment 1 denoted by the same reference signs, and detailed description thereof will be omitted. In FIG. 4, while the surface 9 is actually covered with the electrically-conductive surface treatment portion 10, the surface 9 is illustrated in a partially removed manner for the convenience of explanation.

In FIG. 4, in a wire harness 1 according to Embodiment 3, the number of grooves 11 serving as portions for relieving stress is increased in the wire harness 1 according to Embodiment 1. In Embodiment 3, an example in which the number of grooves 11 is increased from one to four is illustrated. The four grooves 11 are twisted at predetermined intervals and in the same direction. The number is exemplary. In addition, the shape and width of each groove 11 are changed slightly.

Accordingly, also in the wire harness 1 according to Embodiment 3, it is a matter of course that similar advantages to those in Embodiment 1 can be obtained.

The metal wire 18 in Embodiment 2 (see FIG. 3) may be provided to be wound around each groove 11 in Embodiment 3. In the case of Embodiment 3, four metal wires 18 are wound.

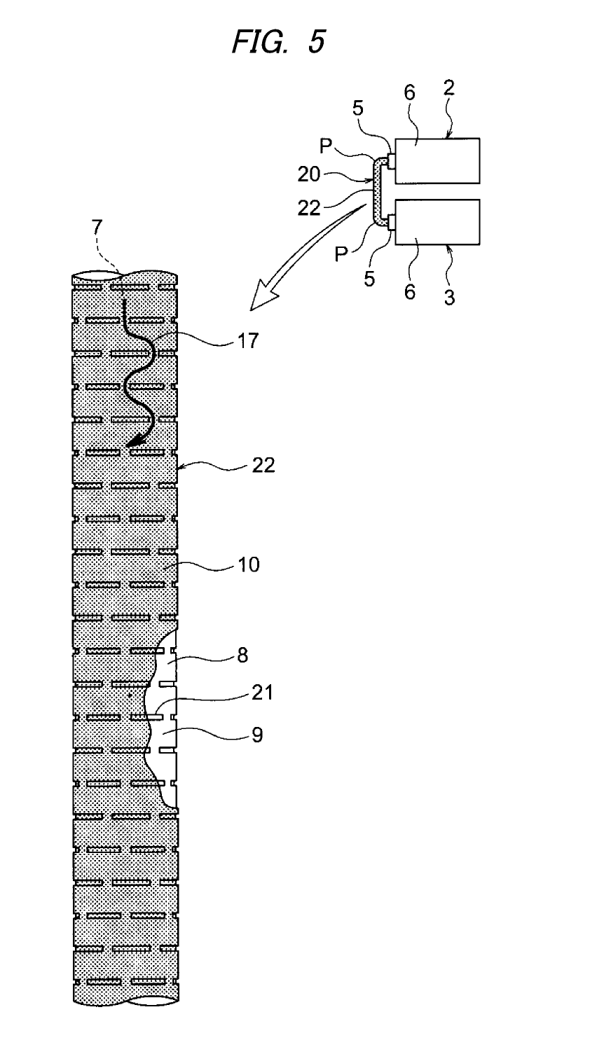

Embodiment 4 will be described below with reference to the drawings. FIG. 5 includes a diagram of a wire harness according to the present invention, and an external view of a surface treated shielded wire. Components that are basically the same as those of Embodiment 1 denoted by the same reference signs, and detailed description thereof will be omitted. In FIG. 5, while the surface 9 is actually covered with the electrically-conductive surface treatment portion 10, the surface 9 is illustrated in a partially removed manner for the convenience of explanation.

In FIG. 5, in a wire harness 20 according to Embodiment 44, the surface treated shielded wire in the wire harness 1 according to Embodiment 1 is replaced by a surface treated shielded wire 22 including a plurality (large number) of recess portions 21 as portions for relieving stress. That is, the wire harness 20 has a configuration including one or plural surface treated shielded wires 22 each having recess portions 21, and counterpart connection portions 5, 5 provided at ends of each surface treated shielded wire 22.

The wire harness 20 is formed so that the wire harness 20 can be wired in a predetermined path between the high voltage device 2, 3. The wire harness 20 has shield performance, and is electrically connected to shield cases 6, 6 of the respective high voltage device 2, 3.

Each surface treated shielded wire 22 has a configuration including a conductor 7 (see FIG. 2. The same thing can be applied to the following members), an insulative coating 8 (insulator) provided on an outer side of the conductor 7, and an electrically-conductive surface treatment portion 10 that is applied to a surface 9 of the insulative coating 8 so as to shield a predetermined range (e.g., a range covering the entire length).

In each end of the surface treated shielded wire 22, the insulative coating 8 is removed by a predetermined length and processed to expose the conductor 7 having electrical conductivity, in the same manner as in Embodiment 1. That is, the terminal is processed so that it can be connected to a terminal 12 (see FIG. 2). The insulative coating 8 is formed out of a resin material having an insulating property and extruded to the outside of the conductor 7. A plurality (large number) of recess portions 21 are formed in the surface 9 of the insulative coating 8.

Each recess portion 21 is formed by denting the surface 9 toward the conductor 7. The recess portion 21 is a dent shaped into a slit or a notch. A plurality of recess portions 21 are formed and disposed circumferentially. The recess portions 21 do not have to be disposed circumferentially, but grooves formed spirally as in Embodiments 1 to 3 may be divided in the spiral direction to form a plurality of recess portions 21. The recess portions 21 are, for example, formed by surface processing in which a mold is pressed against the insulative coating 8 that is soft immediately after extrusion molding. The recess portions 21 are formed along the entire length of the surface treated shielded wire 22 in the embodiment.

The surface 9 is not segmented by the recess portions 21. That is, even when the recess portions 21 are formed, the surface 9 of the insulative coating 8 is continuous all over the length in its axial direction. Although the recess portions 21 are formed along the entire length of the surface treated shielded wire 22 in the embodiment as described above, it will go well only if the recess portions 21 are formed and disposed in at least a position corresponding to the wire bent portion P. The widths and layout of the recess portions 21 are set suitably in accordance with the use form of the wire harness 20. In addition, the depths of the recess portions 21 are set suitably in consideration of the insulating performance etc.

The recess portions 21 are formed as portions on which possible excessive stress applied, for example, when the surface treated shielded wire 22 is bent can be concentrated in the wire bent portion P.

The electrically-conductive surface treatment portion 10 is an electrically-conductive surface treatment portion applied on the surface 9 and the recess portions 21 of the insulative coating 8, and in this embodiment, is formed in a similar manner as Embodiment 1.

In the aforementioned configuration and structure, assume that stress during bending may be, for example, applied on the surface treated shielded wire 22 when the wire harness 20 is wired in a predetermined path. Even in this case, the stress is concentrated at the recess portions 21 formed in the surface treated shielded wire 22 so that stress concentration on the surface 9 side can be relieved. Thus, a large crack or breakage of the electrically-conductive surface treatment portion 10 is prevented.

As is understood from the above description, the recess portions 21 serve as stress concentration portions in the wire harness 1. Accordingly, even if the electrically-conductive surface treatment portion 10 suffers sudden bending or excessive bending or even if the electrically-conductive surface treatment portion 10 is exposed to mechanical stress, the electrically-conductive surface treatment portion 10 applied to the recess portions 21 can be cracked first, so that the electrically-conductive surface treatment portion 10 applied on the surface 9 of the insulative coating 8 can be prevented from being cracked. That is, the electrically-conductive surface treatment portion 10 applied on the surface 9 of the insulative coating 8 can maintain shield performance. That is, a conduction path 17 shown by the arrow in FIG. 5 is secured so that the shield performance can be maintained surely.

Thus, the wire harness 20 according to Embodiment 4 also has similar advantages to those in Embodiment 1.

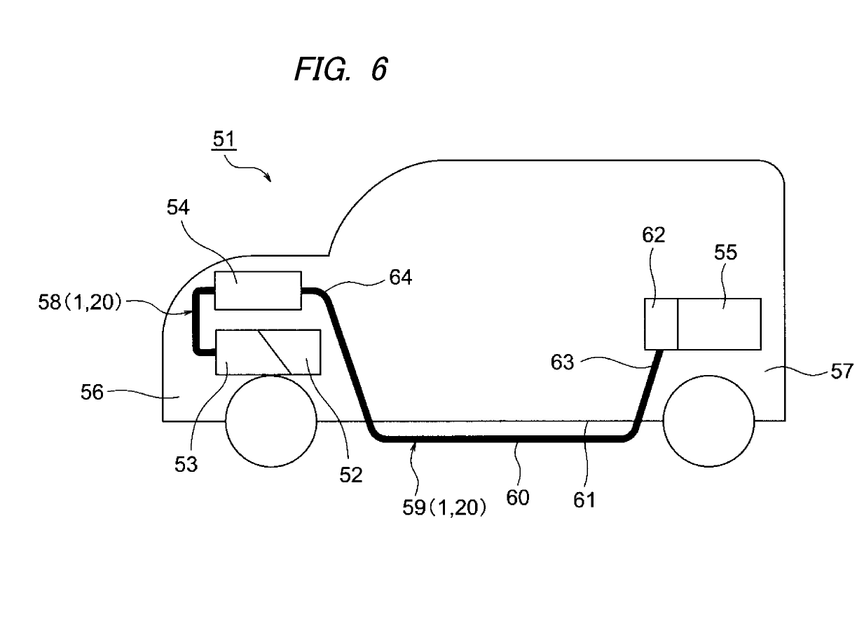

Embodiment 5 will be described below with reference to the drawings. FIG. 6 is a diagram illustrating a location where a wire harness according to the present invention is arranged in a vehicle.

In FIG. 6, the reference sign 51 represents a hybrid car (which may be replaced by an electric car or an ordinary car). The hybrid car 51 is a vehicle that is driven by a mixture of two power sources, that is, an engine 52 and a motor unit 53. To the motor unit 53, electric power is supplied from a battery 55 (battery pack) through an inverter unit 54. In this embodiment, the engine 52, the motor unit 53 and the inverter unit 54 are mounted in an engine room 56 located in a site where there are front wheels etc. On the other hand, the battery 55 is mounted in a car rear portion 57 located in a site where there are rear wheels etc. The battery 55 may be mounted in a car cabin that is located at the rear of the engine room 56.

The motor unit 53 and the inverter unit 54, which are high voltage device, are connected through a high voltage wire harness 58 (motor cable). In addition, the battery 55 and the inverter unit 54 are also connected through a high voltage wire harness 59. One of the wire harnesses 1 and 20 according to Embodiment 1 to Embodiment 4 is used as each wire harness 58, 59.

Three surface treated shielded wires 4 (22) are used for the wire harness 58, whereas two surface treated shielded wires 4 (22) are used for the wire harness 59. In addition, an exterior member or the like for covering the surface treated shielded wires 4 (22) in a lump is used in accordance with necessity.

An intermediate portion 60 of the wire harness 59 is wired in an vehicle underfloor 61. In addition, the wire harness 59 is wired substantially in parallel with the vehicle underfloor 61. The wire harness 59 and the battery 55 are connected through a junction block 62 that is provided in the battery 55. A rear end 63 of the wire harness 59 is electrically connected to the junction block 62 by a well-known method (e.g., using the counterpart connection portion 5 in FIG. 2). On the other hand, a front end 64 of the wire harness 59 is electrically connected to the inverter unit 54 in the same manner.

Further, it is a matter of course that various changes may be made to implement the present invention without changing the gist of the invention.

Here, some features of the shielded wires and the wire harnesses according to the aforementioned embodiments of the present invention will be summarized briefly and listed in the following [1] to [4].

[1] A shielded wire (a surface treated shielded wire 4) including:

a conductor (7);

an insulative coating (8) provided on an outer side of the conductor and having a surface formed with a recess portion (groove 11); and

an electrically-conductive surface treatment portion (10) applied on at least a surface of the insulative coating other than the recess portion from one end to another end, in an extending direction of the conductor, of a predetermined range on the insulative coating.

[2] The shielded wire according to [1] described above, wherein the recess portion is formed at a location on the insulative coating corresponding to a bent portion (wire bent portion P) of the shielded wire.
[3] The shielded wire according to [1] or [2] described above, further including a first electrically-conductive member (metal wire 18) provided in the recess portion.
[4] A wire harness (1) including:

the shielded wire according to any one of [1] to [3] described above; and

a counterpart connection portion (5) provided at an end of the shielded wire, the counterpart connection portion being electrically connected to the electrically-conductive surface treatment portion.

While the present invention has been described in detail with reference to certain embodiments thereof, it is apparent for those skilled in the art that various changes and modifications may be made therein without departing from the spirit and scope of the invention.

What is claimed is:

1. A shielded wire comprising:
a conductor;
an insulative coating provided on an outer side of the conductor and having a surface formed with a recess portion; and
an electrically-conductive surface treatment portion applied on at least a surface of the insulative coating other than the recess portion from one end to another end, in an extending direction of the conductor, of a predetermined range on the insulative coating.

2. The shielded wire according to claim 1, wherein the recess portion is formed at a location on the insulative coating corresponding to a bent portion of the shielded wire.

3. The shielded wire according to claim 1, further comprising a first electrically-conductive member provided in the recess portion.

4. A wire harness comprising:
a shielded wire; and
a counterpart connection portion provided at an end of the shielded wire,
wherein the shielded wire comprises:
a conductor;
an insulative coating provided on an outer side of the conductor and having a surface formed with a recess portion; and
an electrically-conductive surface treatment portion applied on at least a surface of the insulative coating other than the recess portion from one end to another end, in an extending direction of the conductor, of a predetermined range on the insulative coating, and
wherein the counterpart connection portion being electrically connected to the electrically-conductive surface treatment portion.
